(19) United States
(12) Patent Application Publication
(10) Pub. No.: US 2025/0294969 A1
(43) Pub. Date: Sep. 18, 2025

(54) DISPLAY DEVICE, METHOD FOR MANUFACTURING THE DISPLAY DEVICE, AND HEAD MOUNTED DISPLAY INCLUDING THE DISPLAY DEVICE

(71) Applicant: Samsung Display Co., LTD., Yongin-si (KR)

(72) Inventor: Chun Gi YOU, Yongin-si (KR)

(73) Assignee: Samsung Display Co., LTD., Yongin-si (KR)

(21) Appl. No.: 19/018,159

(22) Filed: Jan. 13, 2025

(30) Foreign Application Priority Data
Mar. 12, 2024 (KR) 10-2024-0034617

(51) Int. Cl. H10K 59/122; H10K 59/12; H10K 59/124

(52) U.S. Cl. CPC H10K 59/122; H10K 59/1201; H10K 59/124

(57) ABSTRACT

Provided are a display device, a method for manufacturing the display device, and a head mounted display including the display device. A display device includes an insulating layer disposed on a substrate, a first electrode disposed on the insulating layer, a first pixel defining layer covering a portion of the first electrode, a second pixel defining layer disposed on the first pixel defining layer, a trench penetrating the insulating layer, the first pixel defining layer, and the second pixel defining layer, a light emitting stack disposed on an upper surface of the first electrode and the second pixel defining layer, and a second electrode disposed on the light emitting stack. A width of an entrance of the trench in a direction is greater than a width of a lower surface of the trench in the direction.

### CROSS-REFERENCE TO RELATED APPLICATION(S)

This application claims priority to and benefits of Korean Patent Application No. 10-2024-0034617 under 35 U.S.C. § 119, filed on Mar. 12, 2024, in the Korean Intellectual Property Office, the entire contents of which are incorporated herein by reference.

### BACKGROUND

### 1. Technical Field

Aspects of one or more embodiments of the disclosure relate to a display device, a method for manufacturing the display device, and a head mounted display including the display device.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDOS is an image display device in which an organic light emitting diode (OLED) is disposed on a semiconductor wafer substrate including complementary metal oxide semiconductor (CMOS).

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure include a display device capable of providing a high-resolution image.

Aspects of the disclosure include a method for manufacturing a display device capable of providing a high-resolution image.

Aspects of the disclosure include a head mounted display capable of providing high-resolution images.

However, embodiments are not limited to those set forth herein. The above and other embodiments will become more apparent to one of ordinary skill in the art to which the disclosure pertains by referencing the detailed description of the disclosure given below.

According to the disclosure, a display device may include an insulating layer disposed on a substrate; a first electrode disposed on the insulating layer; a first pixel defining layer covering a portion of the first electrode; a second pixel defining layer disposed on the first pixel defining layer; a trench penetrating the insulating layer, the first pixel defining layer, and the second pixel defining layer; a light emitting stack disposed on an upper surface of the first electrode and the second pixel defining layer; and a second electrode disposed on the light emitting stack. A width of an entrance of the trench in a direction is greater than a width of a lower surface of the trench in the direction.

A length of a sidewall of the trench defined by the insulating layer may be greater than a length of a sidewall of the trench defined by the first pixel defining layer and the second pixel defining layer.

A height of the trench may range from about 6,000 Å to about 10,000 Å.

The display device may further include a third pixel defining layer disposed on the second pixel defining layer. The trench may penetrate the third pixel defining layer.

A sum of a thickness of the first pixel defining layer, a thickness of the second pixel defining layer, and a thickness of the third pixel defining layer may be less than or equal to about ¼ of a height of the trench.

An angle formed between an upper surface of the third pixel defining layer and a tangent of a sidewall of the trench at the entrance of the trench may be in a range of about 80° to about 90°.

The light emitting stack may include a first stack layer disposed at an edge of the entrance of the trench, and a second stack layer disposed on the first stack layer.

The light emitting stack may further include a third stack layer disposed on the second stack layer, the third stack layer covering the entrance of the trench.

The display device may further include a third pixel defining layer disposed on the second pixel defining layer. The third pixel defining layer may be disposed on a sidewall and the lower surface of the trench.

The light emitting stack may include a first stack layer disposed on the third pixel defining layer disposed on the sidewall and the lower surface of the trench, and a second stack layer disposed on the first stack layer.

A thickness of the first stack layer disposed on a sidewall of the trench defined by the insulating layer may be less than a thickness of the first stack layer disposed on the lower surface of the trench.

A thickness of the first stack layer disposed on a sidewall of the trench defined by the second pixel defining layer may be greater than a thickness of the first stack layer disposed on a sidewall of the trench defined by the insulating layer.

The light emitting stack may further include a third stack layer disposed on the second stack layer, the third stack layer covering the entrance of the trench.

According to the disclosure, a method for manufacturing a display device may include forming an insulating layer on a substrate; and forming a plurality of first electrodes on the insulating layer; forming a pixel defining layer covering the plurality of first electrodes; forming a plurality of trenches penetrating the pixel defining layer; etching the pixel defining layer to form a pixel defining layer, to partially expose each of the plurality of first electrodes; forming a first stack layer on a portion of each of the plurality of first electrodes and the pixel defining layer; forming a second stack layer on the first stack layer; and forming a second electrode covering the second stack layer. The first stack layer is disposed at an edge of an entrance of the trench, and the second stack layer covers the entrance of the trench.

The forming of the pixel defining layer may include forming a first pixel defining layer covering the first electrodes; forming a second pixel defining layer covering the first pixel defining layer; and forming a third pixel defining layer covering the second pixel defining layer.

The etching of the pixel defining layer to form the pixel defining layer, to partially expose each of the plurality of first electrodes may include forming a first mask pattern on a portion of the third pixel defining layer, and etching the third pixel defining layer which is not covered by the first mask pattern to form a third pixel defining layer, forming a second mask pattern on a portion of the second pixel defining layer and all parts of the third pixel defining layer, and etching the second pixel defining layer which is not covered by the second mask pattern to form a second pixel defining layer, and forming a third mask pattern on a portion of the first pixel defining layer, and all parts of the second pixel defining layer and the third pixel defining layer, and etching the first pixel defining layer which is not covered by the third mask pattern to partially expose each of the first electrodes.

According to the disclosure, a method for manufacturing a display device may include forming an insulating layer on a substrate; and forming a plurality of first electrodes on the insulating layer; forming a first pixel defining layer covering the plurality of first electrodes; and forming a second pixel defining layer on the first pixel defining layer; forming a plurality of trenches penetrating the first pixel defining layer and the second pixel defining layer; forming a third pixel defining layer on the second pixel defining layer; etching each of the first pixel defining layer, the second pixel defining layer, and the third pixel defining layer to form a first pixel defining layer, a second pixel defining layer, and a third pixel defining layer, to partially expose each of the plurality of first electrodes; forming a first stack layer on a portion of each of the plurality of first electrodes, the first pixel defining layer, the second pixel defining layer, and the third pixel defining layer; forming a second stack layer on the first stack layer, and forming a second electrode covering the second stack layer. The third pixel defining layer is disposed on a sidewall and a lower surface of the trench. The first stack layer is disposed on the third pixel defining layer disposed on the sidewall and the lower surface of the trench. The second stack layer covers an entrance of the trench.

The forming of the first pixel defining layer and the second pixel defining layer may include forming a first pixel defining layer covering the first electrodes, and forming a second pixel defining layer covering the first pixel defining layer.

The etching of each of the first pixel defining layer, the second pixel defining layer, and the third pixel defining layer to form the first pixel defining layer, the second pixel defining layer, and the third pixel defining layer, to partially expose each of the plurality of first electrodes may include forming a first mask pattern on a portion of the third pixel defining layer, and etching the third pixel defining layer which is not covered by the first mask pattern to form a third pixel defining layer, forming a second mask pattern on a portion of the second pixel defining layer and all parts of the third pixel defining layer, and etching the second pixel defining layer which is not covered by the second mask pattern to form a second pixel defining layer, and forming a third mask pattern on a portion of the first pixel defining layer, and all parts of the second pixel defining layer and the third pixel defining layer, and etching the first pixel defining layer which is not covered by the third mask pattern to partially expose each of the first electrodes.

According to the disclosure, a head mounted display may include at least one display device, a display device housing that accommodates the at least one display device, and an optical member that magnifies a display image of the at least one display device or change an optical path. The at least one display device may include an insulating layer disposed on a substrate; a first electrode disposed on the insulating layer, a first pixel defining layer covering a portion of the first electrode, a second pixel defining layer disposed on the first pixel defining layer, a trench penetrating the insulating layer, the first pixel defining layer, and the second pixel defining layer, a light emitting stack disposed on an upper surface of the first electrode and the second pixel defining layer, and a second electrode disposed on the light emitting stack. A width of an entrance of the trench in a direction is greater than a width of a lower surface of the trench in the direction.

According to the disclosure, a first stack layer, a second stack layer, and a charge generation layer between the first stack layer and the second stack layer may be cut off by a plurality of trenches. Accordingly, it is possible to prevent a current flowing in each of sub-pixels from flowing to the neighboring sub-pixel through the charge generation layer.

According to the disclosure, the plurality of trenches may be formed by a lithography process using argon fluoride (ArF) as a photoresist so that a width of an entrance of the trench may be formed to be greater than about 100 μm and less than about 130 μm. Therefore, the first stack layer, the second stack layer, and the charge generation layer between the first stack layer and the second stack layer may be reliably cut off in the trench.

According to the disclosure, in case that a trench is formed by a photolithography process using krypton fluoride (KrF), it is difficult to control the width of the entrance of the trench to be less than about 130 nm. Thus, a third pixel defining may be formed on the sidewall and lower surface of the trench. Accordingly, the width of the entrance of the trench may be formed to be greater than about 100 μm and less than about 130 μm by the third pixel defining layer, so that the first stack layer, the second stack layer, and the charge generation layer between the first stack layer and the second stack layer may be reliably cut off in the trench.

### BRIEF DESCRIPTION OF THE DRAWINGS

The above and other embodiments and features of the disclosure will become more apparent by describing aspects of embodiments thereof with reference to the attached drawings, in which:

FIG. 1 is an exploded schematic perspective view showing a display device according to an embodiment;

FIG. 2 is a block diagram illustrating a display device according to an embodiment;

FIG. 3 is a schematic diagram of an equivalent circuit of a first sub-pixel according to an embodiment;

FIG. 4 is a plan diagram illustrating an example of a display panel according to an embodiment;

FIGS. 5 and 6 are plan diagrams illustrating embodiments of the display area of FIG. 4;

FIG. 7 is a schematic cross-sectional view illustrating an example of a display panel taken along line I1-I1′ of FIG. 5;

FIG. 8 is a schematic cross-sectional view showing an area A1 of FIG. 7 in detail;

FIG. 9 is a schematic cross-sectional view illustrating an example of an area A2 of FIG. 8;

FIG. 10 is a schematic cross-sectional view showing another example of an area A1 of FIG. 7;

FIG. 11 is a schematic cross-sectional view illustrating an example of an area A3 of FIG. 10;

FIG. 12 is a flowchart illustrating a method for manufacturing a display panel according to an embodiment;

FIGS. 13 to 18 are schematic cross-sectional views showing an area A1 in detail to describe a method for manufacturing a display panel according to an embodiment;

FIG. 19 is a flowchart illustrating a method for manufacturing a display panel according to an embodiment;

FIGS. 20 to 24 are schematic cross-sectional views showing an area A1 in detail to describe a method for manufacturing a display panel according to an embodiment;

FIG. 25 is a schematic perspective view illustrating a head mounted display according to an embodiment;

FIG. 26 is an exploded schematic perspective view illustrating an example of the head mounted display of FIG. 25; and

FIG. 27 is a schematic perspective view illustrating a head mounted display according to an embodiment.

### DETAILED DESCRIPTION OF THE EMBODIMENTS

Aspects and features of embodiments of the disclosure and methods of accomplishing the same may be understood more readily by reference to the detailed description of embodiments and the accompanying drawings. Hereinafter, aspects of embodiments will be described in more detail with reference to the accompanying drawings. The described embodiments, however, may be embodied in various different forms, and should not be construed as being limited to only the illustrated embodiments herein. Rather, these embodiments are provided as examples so that the disclosure will be thorough and complete, and will fully convey the aspects and features of the disclosure to those skilled in the art. Accordingly, processes, elements, and techniques that may not be necessary to those having ordinary skill in the art for a complete understanding of the aspects and features of the disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, structural or functional descriptions disclosed herein are illustrative for the purpose of describing embodiments according to the disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the disclosure.

In the detailed description, for the purposes of explanation, numerous details are set forth to provide a thorough understanding of various embodiments. It is apparent, however, that various embodiments may be practiced without these details or with one or more equivalent arrangements. In other instances, structures and devices may be shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B.

As used herein, the term “and/or” includes any and all combinations of one or more of the associated listed items. For example, the expression such as “A and/or B” may include A, B, or A and B. Further, the use of “may” when describing embodiments of the disclosure refers to one or more embodiments of the disclosure.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments and is not intended to be limiting of the disclosure. As used herein, the singular forms “a” and “an” are intended to include the plural forms as well, unless the context clearly indicates otherwise.

It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value. Further, the use of “may” when describing embodiments of the disclosure refers to “one or more embodiments of the disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

The electronic or electric devices and/or any other relevant devices or components according to one or more embodiments of the disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like within the spirit and the scope of the disclosure. Also, a person of skill in the art should recognize that the functionality of various computing devices may be combined or integrated into a single computing device, or the functionality of a computing device may be distributed across one or more other computing devices without departing from the spirit and scope of the disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the specification, and should not be interpreted in an idealized or overly formal sense, unless expressly so defined herein.

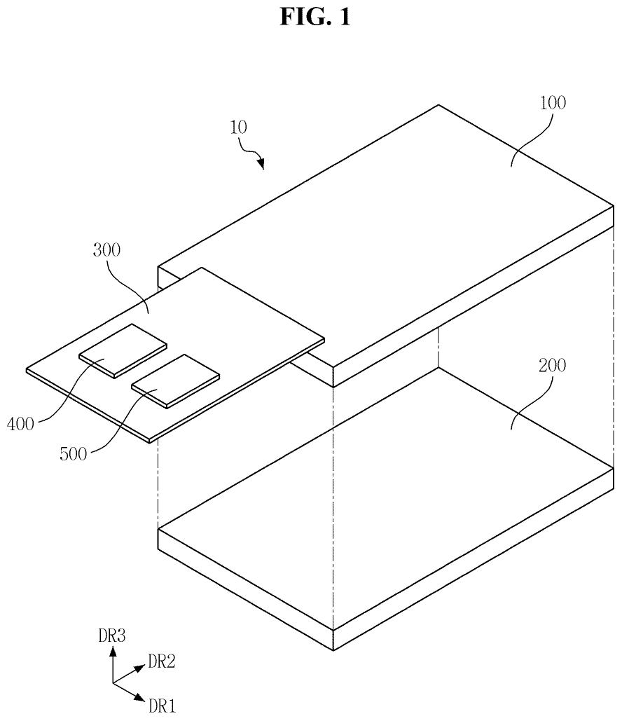

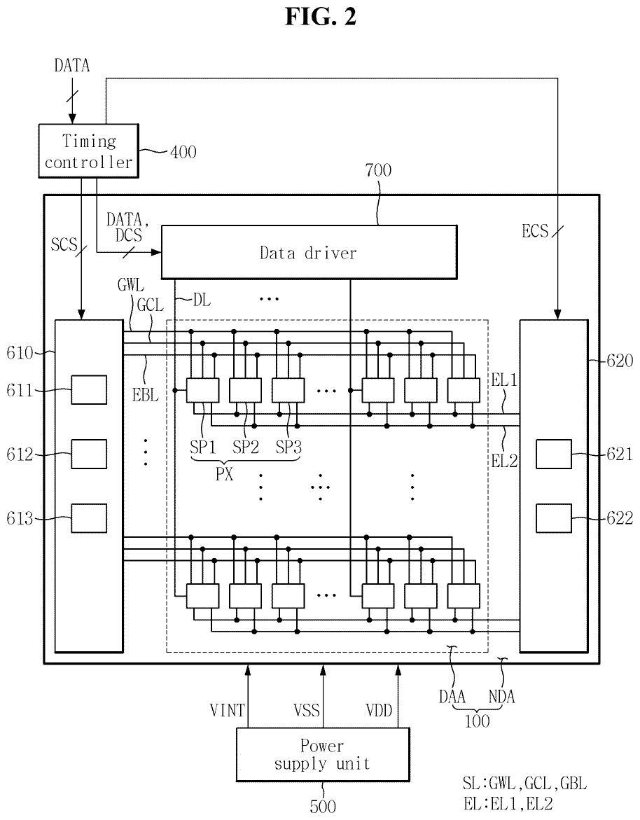

FIG. 1 is an exploded schematic perspective view showing a display device according to an embodiment. FIG. 2 is a block diagram illustrating a display device according to an embodiment.

Referring to FIGS. 1 and 2, a display device 10 according to an embodiment is a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like within the spirit and the scope of the disclosure. For example, the display device 10 according to an embodiment may be applied as a display unit of a television, a laptop, a monitor, a billboard, or an Internet-of-Things (IoT) terminal. By way of example, the display device 10 according to an embodiment may be applied to a smart watch, a watch phone, a head mounted display (HMD) for implementing virtual reality and augmented reality, and the like within the spirit and the scope of the disclosure.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the specification is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be disposed in the display area DAA. The plurality of pixels PX may be arranged or disposed in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL may include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

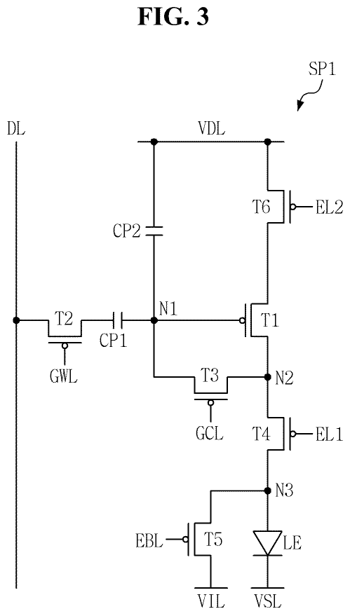

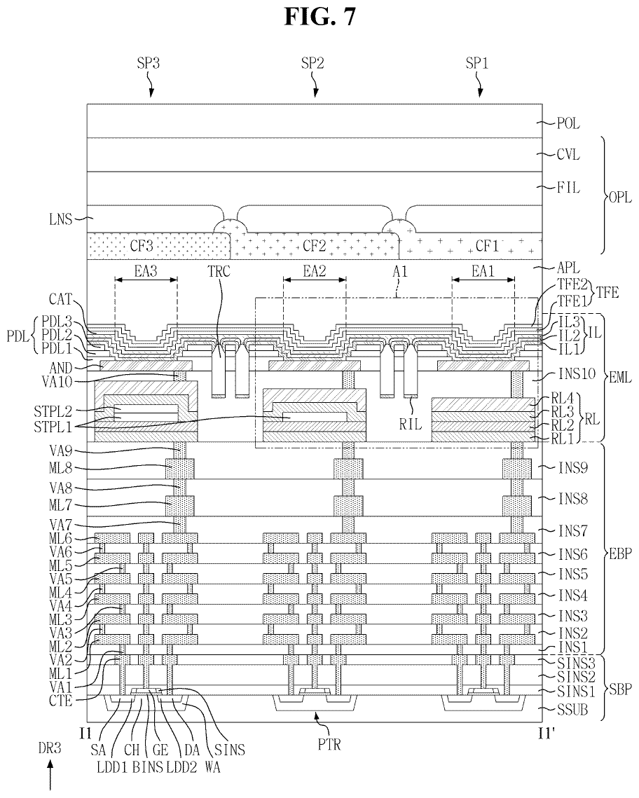

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of the data driver 700 may be formed of complementary metal oxide semiconductor (CMOS), but the embodiment of the specification is not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line EBL among the plurality of bias scan lines EBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light emitting transistors. The plurality of scan transistors and the plurality of light emitting transistors may be formed on the semiconductor substrate SSUB (sec FIG. 7) through a semiconductor process. For example, the plurality of scan transistors and the plurality of light emitting transistors may be formed of CMOS, but the embodiment of the specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (sec FIG. 7) through a semiconductor process. For example, the plurality of data transistors may be formed of CMOS, but the embodiment of the specification is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. For example, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface or a surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

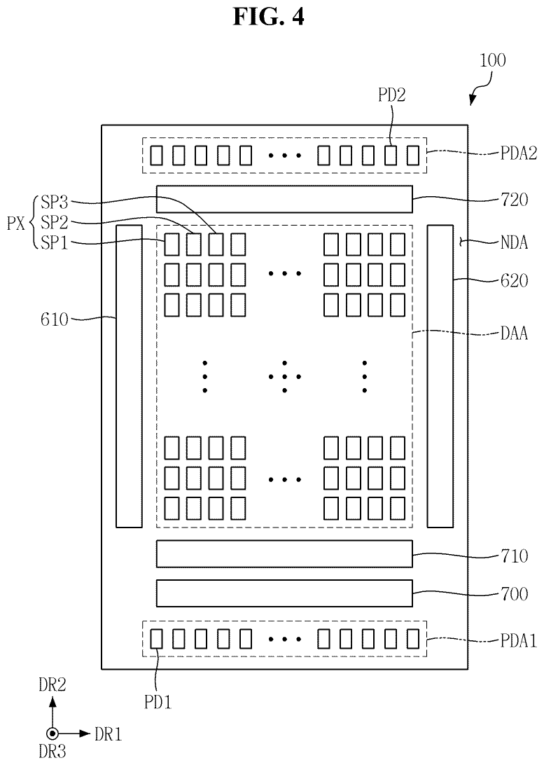

The circuit board 300 may be electrically connected to a plurality of first pads PD1 (see FIG. 4) of a first pad portion PDA1 (see FIG. 4) of the display panel 100 by using a conductive adhesive member such as an anisotropic conductive layer. The circuit board 300 may be a flexible printed circuit board with a flexible material, or a flexible film. Although the circuit board 300 is illustrated in FIG. 1 as being unfolded, the circuit board 300 may be bent. For example, one end or an end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface or a surface of the circuit board 300. For example, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

By way of example, each of the timing control circuit 400 and the power supply circuit 500 may be disposed in the non-display area NDA of the display panel 100, similarly to the scan driver 610, the emission driver 620, and the data driver 700. For example, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS, but the embodiment of the specification is not limited thereto. Each of the timing control circuit 400 and the power supply circuit 500 may be disposed between the data driver 700 and the first pad portion PDA1 (see FIG. 4).

FIG. 3 is a schematic diagram of an equivalent circuit of a first sub-pixel according to an embodiment.

Referring to FIG. 3, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. For example, the first driving voltage VSS may be lower than the third driving voltage VINT. The second driving voltage VDD may be higher than the third driving voltage VINT.

The first sub-pixel SP1 may include a plurality of transistors T1 to T6, a light emitting clement LE, a first capacitor CP1, and a second capacitor CP2.

The light emitting element LE emits light in response to a driving current Ids flowing through the channel of a first transistor T1. The emission amount of the light emitting element LE may be proportional to the driving current Ids. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the specification is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the specification is not limited thereto. Each of the first to sixth transistors T1 to T6 may be an N-type MOSFET. By way of example, some of the first to sixth transistors T1 to T6 may be P-type MOSFETs, and each of the remaining transistors may be an N-type MOSFET.

Although it is illustrated in FIG. 3 that the first sub-pixel SP1 may include six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 may be omitted in the specification.

FIG. 4 is a plan diagram illustrating an example of a display panel according to an embodiment.

Referring to FIG. 4, the display area DAA of the display panel 100 according to an embodiment may include the plurality of pixels PX arranged or disposed in a matrix form. The non-display area NDA of the display panel 100 according to an embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side or a side of the display area DAA in the first direction DR1, and the emission driver 620 may be disposed on the other side of the display area DAA in the first direction DR1. For example, the scan driver 610 may be disposed on the left side of the display area DAA, and the emission driver 620 may be disposed on the right side of the display area DAA. However, the embodiment of the specification is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side or a side of the display area DAA in the second direction DR2. The first pad portion PDA1 may be disposed outside the data driver 700 in the second direction DR2. For example, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. For example, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side or a side of the display area DAA in the second direction DR2. For example, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

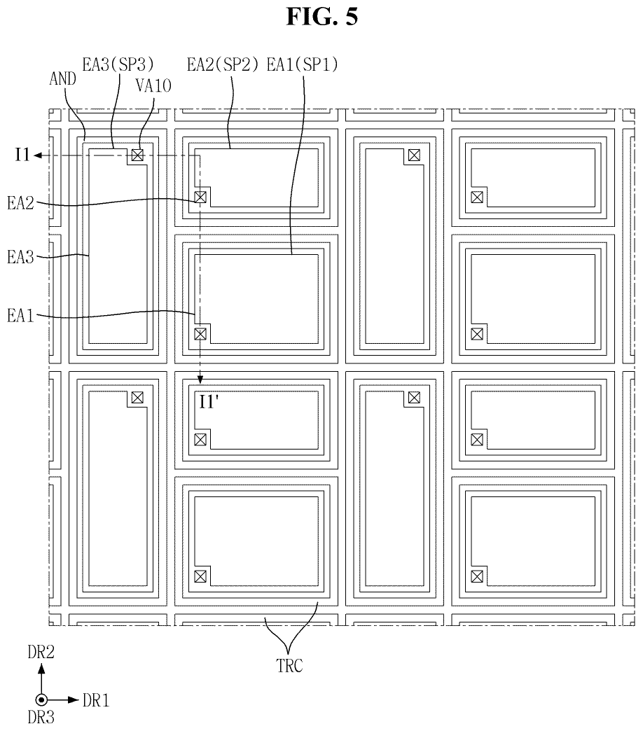

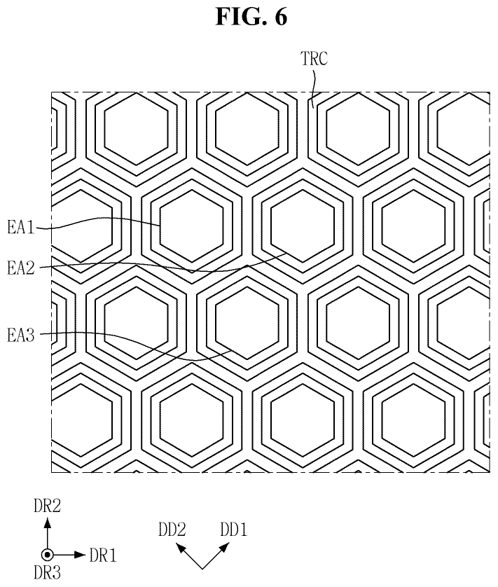

FIGS. 5 and 6 are plan diagrams illustrating embodiments of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in plan view.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2. The first emission area EA1, the second emission area EA2, and the third emission area EA3 may have, in plan view, a hexagonal shape formed of six straight lines as shown in FIGS. 5 and 6, but the embodiment of the specification is not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. The second emission area EA2 and the third emission area EA3 may be adjacent to each other in the second direction DR2. The area of the first emission area EA1, the area of the second emission area EA2, and the area of the third emission area EA3 may be different.

By way of example, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit first light, the second emission area EA2 may emit second light, and the third emission area EA3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is illustrated in FIGS. 5 and 6 that each of the plurality of pixels PX may include three emission areas EA1, EA2, and EA3, but the embodiment of the specification is not limited thereto. For example, each of the plurality of pixels PX may include four emission areas.

The plan of the emission areas of the plurality of pixels PX is not limited to that illustrated in FIGS. 5 and 6. For example, the emission areas of the plurality of pixels PX may be disposed in a stripe structure in which the emission areas are arranged or disposed in the first direction DR1, a PENTILE™ structure in which the emission areas are arranged or disposed in a diamond shape, or a hexagonal structure in which the emission areas having, in plan view, a hexagonal shape are arranged or disposed side by side as shown in FIG. 6.

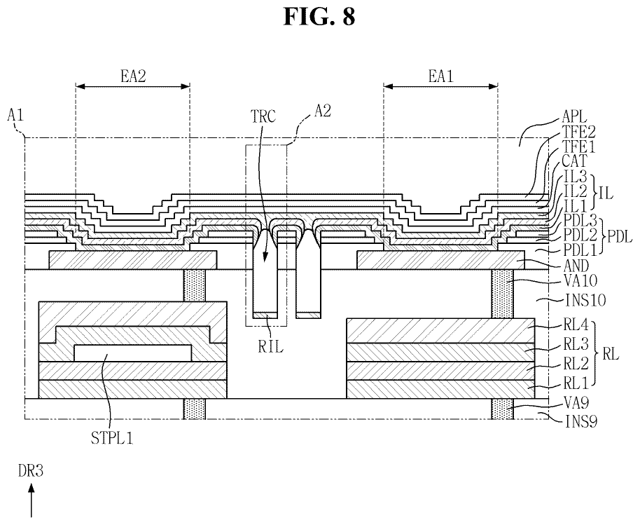

FIG. 7 is a schematic cross-sectional view illustrating an example of a display panel taken along line I1-I1′ of FIG. 5. FIG. 8 is a schematic cross-sectional view showing an area A1 of FIG. 7 in detail.

Referring to FIGS. 7 and 8, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the upper surface of the semiconductor substrate SSUB. The plurality of well regions WA may be regions doped with a second type impurity. The second type impurity may be different from the aforementioned first type impurity. For example, in case that the first type impurity is a p-type impurity, the second type impurity may be an n-type impurity. By way of example, in case that the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side or a side of the gate electrode GE, and the drain region SA may be disposed on the other side of the gate electrode GE.

Each of the plurality of well regions WA further may include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOₓ)-based inorganic layer, but the embodiment of the specification is not limited thereto.

A second semiconductor insulating layer SINS2 may be disposed on the first semiconductor insulating layer SINS1. The second semiconductor insulating layer SINS2 may be formed of a silicon oxide (SiOₓ)-based inorganic layer, but the embodiment of the specification is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The upper surface of each of the plurality of contact terminals CTE may be exposed without being covered by the third semiconductor insulating layer SINS3. The third semiconductor insulating layer SINS3 may be formed of a silicon oxide (SiOₓ)-based inorganic layer, but the embodiment of the specification is not limited thereto.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The light emitting clement backplane EBP may include a plurality of conductive layers ML1 to ML8, a plurality of vias VA1 to VA9, and a plurality of insulating layers INS1 to INS10. The light emitting element backplane EBP may include a plurality of insulating layers INS1 to INS10 disposed between first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown in FIG. 4. For example, the first to sixth transistors T1 to T6 may be formed on the semiconductor backplane SBP, and the connection of the first to sixth transistors T1 to T6 and the first and second capacitors C1 and C2 is accomplished through the first to eighth conductive layers ML1 to ML8. The connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first insulating layer INS1 may be disposed on the semiconductor backplane SBP. Each of the first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

The second insulating layer INS2 may be disposed on the first insulating layer INS1 and the first conductive layers ML1. Each of the second vias VA2 may penetrate the second insulating layer INS2 and be connected to the exposed first conductive layer ML1. Each of the second conductive layers ML2 may be disposed on the second insulating layer INS2 and may be connected to the second via VA2.

The third insulating layer INS3 may be disposed on the second insulating layer INS2 and the second conductive layers ML2. Each of the third vias VA3 may penetrate the third insulating layer INS3 and be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of the fourth vias VA4 may penetrate the fourth insulating layer INS4 and be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of the sixth vias VA6 may penetrate the sixth insulating layer INS6 and be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOₓ)-based inorganic layer, but the embodiment of the specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1,360 Å; the thickness of each of the second conductive layer ML2, the third conductive layer ML3, the fourth conductive layer ML4, the fifth conductive layer ML5, and the sixth conductive layer ML6 may be about 1,440 Å; and the thickness of each of the first via VA1, the second via VA2, the third via VA3, the fourth via VA4, the fifth via VA5, and the sixth via VA6 may be about 1,150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9,000 Å. The thickness of each of the seventh via VA7 and the eighth via VA8 may be about 6,000 Å.

A ninth insulating layer INS9 may be disposed on the eighth insulating layer INS8 and the eighth conductive layer ML8. The ninth insulating layer INS9 may be formed of a silicon oxide (SiOₓ)-based inorganic layer, but the embodiment of the specification is not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be about 16,500 Å.

The display element layer EML may be disposed on the light emitting element backplane EBP. The display element layer EML may include light emitting elements LE each including a reflective electrode layer RL, a tenth insulating layer INS10, a tenth via VA10, the first electrode AND, a light emitting stack IL, and a second electrode CAT; a pixel defining layer PDL; and a plurality of trenches TRC.

The reflective electrode layer RL may be disposed on the ninth insulating layer INS9. The reflective electrode layer RL may include one or more reflective electrodes RL1, RL2, RL3, and RL4, a first step layer STPL1, and a second step layer STPL2. For example, FIG. 7 illustrates that the one or more reflective electrodes RL1, RL2, RL3, and RL4 include first to fourth reflective electrodes RL1, RL2, RL3, and RL4, but the embodiment of the disclosure is not limited thereto.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. The second step layer STPL2 may not be disposed on the first step layer STPL1 in the second sub-pixel SP2.

The thickness of the first step layer STPL1 may be set in consideration of the wavelength of the first light and a distance from the light emitting stack IL of the second sub-pixel SP2 to the fourth reflective electrode RL4 to advantageously reflect the light of first color emitted from the light emitting stack IL. The thickness of the second step layer STPL2 may be set in consideration of the wavelength of the first light and a distance from the light emitting stack IL of the third sub-pixel SP3 to the fourth reflective electrode RL4 to advantageously reflect the first light emitted from the light emitting stack IL.

The first step layer STPL1 and the second step layer STPL2 may be formed of silicon carbonitride (SiCN) or a silicon oxide (SiOₓ)-based inorganic layer, but the embodiment of the specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1. In the third sub-pixel SP3, the third reflective electrode RL3 may be disposed on the second step layer STPL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

At least one of the first reflective electrode RL1, the second reflective electrode RL2, or the third reflective electrode RL3 may be omitted.

The fourth reflective electrodes RL4 may be respectively disposed on the third reflective electrodes RL3. The fourth reflective electrodes RL4 may be a layer that reflects light from the light emitting stack IL. The fourth reflective electrodes RL4 may include metal having high reflectivity to advantageously reflect the light. Since the fourth reflective electrode RL4 is an electrode that substantially reflects light from the light emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include aluminum (Al) or titanium (Ti).

The tenth insulating layer INS10 may be disposed on the ninth insulating layer INS9 and the fourth reflective electrodes RL4. The tenth insulating layer INS10 may be an optical auxiliary layer through which light reflected by the reflective electrode layer RL passes, among light emitted from the light emitting elements LE. The tenth insulating layer INS10 may be formed of a silicon oxide (SiOₓ)-based inorganic layer, but the embodiment of the specification is not limited thereto.

Each of the tenth vias VA10 may penetrate the tenth insulating layer INS10 and be connected to the exposed ninth metal layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The thickness of the tenth via VA10 may vary in the first sub-pixel SP1, the second sub-pixel SP2, and the third sub-pixel SP3 in order to adjust a resonance distance of light emitted from the light emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. For example, the distance between the light emitting stack IL and the reflective electrode layer RL may be different in the first sub-pixel SP1, the second sub-pixel SP2, and the third sub-pixel SP3.

In summary, in order to adjust the distance between the light emitting stack IL and the reflective electrode layer RL according to the main wavelength of light emitted from the first sub-pixel SP1, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light emitting elements LE may be disposed on the tenth insulating layer INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining layer PDL may be disposed on a portion of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack IL, and the second electrode CAT may be sequentially stacked each other in the first sub-pixel SP1 to emit light. The second emission area EA2 may be defined as an area in which the first electrode AND, the light emitting stack IL, and the second electrode CAT may be sequentially stacked each other in the second sub-pixel SP2 to emit light. The third emission area EA3 may be defined as an area in which the first electrode AND, the light emitting stack IL, and the second electrode CAT may be sequentially stacked each other in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but the embodiment of the specification is not limited thereto. The first pixel defining layer PDL1, the second pixel defining layer PDL2, and the third pixel defining layer PDL3 may each have a thickness of about 500 Å.

In case that the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Further, the tenth insulating layer INS10 may be partially recessed at each of the plurality of trenches TRC.

At least one trench TRC may be disposed between adjacent sub-pixels SP1, SP2, and SP3. Although FIG. 7 illustrates that two trenches TRC are disposed between adjacent sub-pixels SP1, SP2, and SP3, the embodiment of the specification is not limited thereto.

The light emitting stack IL may include a plurality of intermediate layers. FIG. 7 illustrates that the light emitting stack IL has a three-tandem structure including the first stack layer IL1, the second stack layer IL2, and the third stack layer IL3, but the embodiment of the specification is not limited thereto. For example, the light emitting stack IL may have a two-tandem structure including two stack layers.

In the three-tandem structure, the light emitting stack IL may have a tandem structure including a plurality of stack layers IL1, IL2, and IL3 that emit different lights. For example, the light emitting stack IL may include the first stack layer IL1 that emits first light, the second stack layer IL2 that emits third light, and the third stack layer IL3 that emits second light. The first stack layer IL1, the second stack layer IL2, and the third stack layer IL3 may be sequentially stacked each other.

The first stack layer IL1 may have a structure in which a first hole transport layer, a first organic light emitting layer that emits first light, and a first electron transport layer may be sequentially stacked each other. The second stack layer IL2 may have a structure in which a second hole transport layer, a second organic light emitting layer that emits third light, and a second electron transport layer may be sequentially stacked each other. The third stack layer IL3 may have a structure in which a third hole transport layer, a third organic light emitting layer that emits second light, and a third electron transport layer may be sequentially stacked each other.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL. A remaining stack layer RIL made of a same material as the first stack layer IL1 may be disposed on the lower surface of each of the trenches TRC. Due to the trench TRC, the first stack layer IL1 may be cut off between adjacent sub-pixels SP1, SP2, and SP3. The second stack layer IL2 may be disposed on the first stack layer IL1. Due to the trench TRC, the second stack layer IL2 may be cut off between adjacent sub-pixels SP1, SP2, and SP3. A void ES or an empty space may be disposed between the remaining stack layer RIL and the second stack layer IL2 in each trench TRC. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the sub-pixels SP1, SP2, and SP3 adjacent to each other.

In the two-tandem structure, each of the plurality of trenches TRC may be a structure for cutting off the charge generation layer and the lower stack layer disposed between the lower stack layer and the upper stack layer.

In order to stably cut off the first stack layer IL1 of the display element layer EML between adjacent sub-pixels SP1, SP2, and SP3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining layer PDL.

FIGS. 7 and 8 illustrate that the first to third stack layers IL1, IL2, and IL3 are all disposed in the first emission area EA1, the second emission area EA2, and the third emission area EA3, but the embodiment of the specification is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. For example, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic layer TFE1 and TFE2 to prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNₓ), silicon oxynitride (SiOₓN_{y}), and silicon oxide (SiOₓ) may be alternately stacked each other. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOₓ) or aluminum oxide (AlOₓ), but the embodiment of the specification is not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit first light, for example, light of a red wavelength band. Thus, the first color filter CF1 may transmit first light among light emitted from the first emission area EA1.

The second color filter CF2 may overlap the second emission area EA2 of the second sub-pixel SP2. The second color filter CF2 may transmit second light, for example, light of a green wavelength band. Thus, the second color filter CF2 may transmit second light among light emitted from the second emission area EA2.

The third color filter CF3 may overlap the third emission area EA3 of the third sub-pixel SP3. The third color filter CF3 may transmit third light, for example, light of a blue wavelength band. Thus, the third color filter CF3 may transmit third light among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Although each of the lenses LNS is illustrated as having a cross-sectional shape that is convex upward, the embodiment of the disclosure is not limited thereto.

The filling layer FIL may be disposed on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be disposed on the filling layer FIL. The cover layer CVL may be a glass substrate or a polymer resin. In case that the cover layer CVL is a glass substrate, it may be attached onto the filling layer FIL. For example, the filling layer FIL may serve to bond the cover layer CVL. In case that the cover layer CVL is a glass substrate, it may serve as an encapsulation substrate. In case that the cover layer CVL is a polymer resin, it may be directly applied onto the filling layer FIL.

The polarizing plate POL may be disposed on one surface or a surface of the cover layer CVL. The polarizing plate POL may be a structure for preventing visibility degradation caused by reflection of external light. The polarizing plate POL may include a linear polarizing plate and a phase retardation film. For example, the phase retardation film may be a λ/4 plate (quarter-wave plate), but the embodiment of the specification is not limited thereto. However, in case that visibility degradation caused by reflection of external light is sufficiently overcome by the first to third color filters CF1, CF2, and CF3, the polarizing plate POL may be omitted.

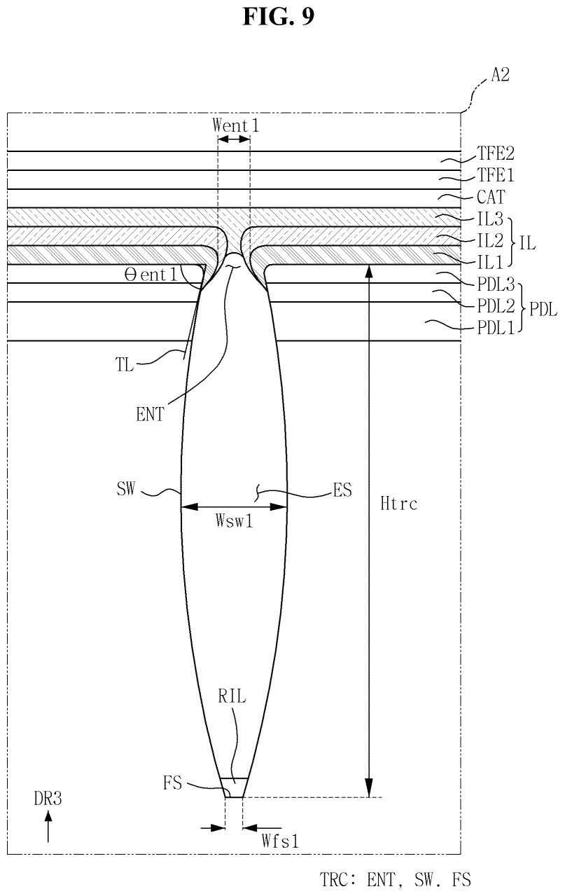

FIG. 9 is a schematic cross-sectional view illustrating an example of an area A2 of FIG. 8.

Referring to FIG. 9, the trench TRC may be a structure for cutting off the charge generation layer between the first stack layer IL1 and the second stack layer IL2 of the light emitting stack IL. The trench TRC may be defined as a hole that penetrates the pixel defining layer PDL and in which the tenth insulating layer INS10 is partially recessed. The trench TRC may be formed by a lithography process using argon fluoride (ArF) as a photoresist.

The trench TRC may include an entrance ENT, a sidewall SW, and a lower surface FS.

The entrance ENT of the trench TRC may be an open area at the top of the trench TRC defined by the third pixel defining layer PDL3. The entrance ENT of the trench TRC may be covered by the light emitting stack IL. For example, the first stack layer IL1 and the second stack layer IL2 may be sequentially disposed at the edge of the entrance ENT of the trench TRC. The entrance ENT of the trench TRC exposed without being covered by the first stack layer IL1 and the second stack layer IL2 may be covered by the third stack layer IL3.

The sidewall SW of the trench TRC may be a side surface that connects the entrance ENT of the trench TRC to the lower surface FS thereof. The sidewall SW of the trench TRC may be defined by the tenth insulating layer INS10 and the pixel defining layer PDL. The length of the sidewall SW of the trench TRC defined by the tenth insulating layer INS10 may be greater than the length of the sidewall SW of the trench TRC defined by the pixel defining layer PDL.

The lower surface FS of the trench TRC may be a closed area at the lower of the trench TRC defined by the tenth insulating layer INS10. The remaining stack layer RIL made of a same material as the first stack layer IL1 may be disposed on the lower surface FS of the trench TRC.

A height Htrc of the trench TRC may be defined as the maximum distance from the lower surface FS of the trench TRC to the entrance ENT of the trench TRC in the third direction DR3. In order to cut off the first to second stack layers IL1 and IL2, the first charge generation layer, and the second charge generation layer in each of the trenches TR, the height Htrc of the trench TRC may range from about 6,000 Å to about 10,000 Å. For example, the height of the pixel defining layer PDL may be about 1,500 Å. For example, the sum of the thickness of the first pixel defining layer PDL1, the thickness of the second pixel defining layer PDL2, and the thickness of the third pixel defining layer PDL3 may be smaller than or equal to ¼ of the height Htrc of the trench TRC.

In order to cut off the first to second stack layers IL1 and IL2, the first charge generation layer, and the second charge generation layer in each of the trenches TRC, an angle θent1 formed between a tangent TL of the sidewall SW of the trench TRC and the upper surface of the third pixel defining layer PDL3 at the entrance of the trench TRC may range from about 80° to about 90°. Accordingly, a maximum width Wsw1 of the trench TRC in one direction or a direction at the center of the sidewall SW may be larger than a width Went1 of the entrance ENT in one direction or a direction and a width Wfs1 of the lower surface FS in one direction or a direction. For example, each of the trenches TRC may have a substantially jar-shaped cross section.

Further, in order to cut off the first to second stack layers IL1 and IL2, the first charge generation layer, and the second charge generation layer in each of the trenches TRC, the width Went1 of the entrance ENT of the trench TRC may be greater than about 100 nm and less than about 130 nm. The width Wfs1 of the lower surface of the trench TRC in one direction or a direction may be less than the width Went1 of the entrance ENT of the trench TRC in one direction or a direction.

The first stack layer IL1 and the second stack layer IL2 may be sequentially disposed at the edge of the entrance ENT of each trench TRC. The first stack layer IL1 may be disposed closer to the edge of the entrance ENT of each trench TRC than the second stack layer IL2. The third stack layer IL3 may be disposed to cover the remaining portion of the entrance ENT of each trench TRC, which is not covered by the first stack layer IL1 and the second stack layer IL2.

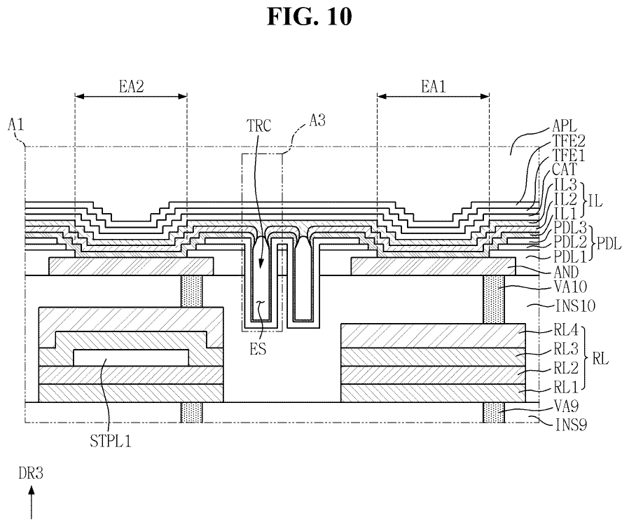

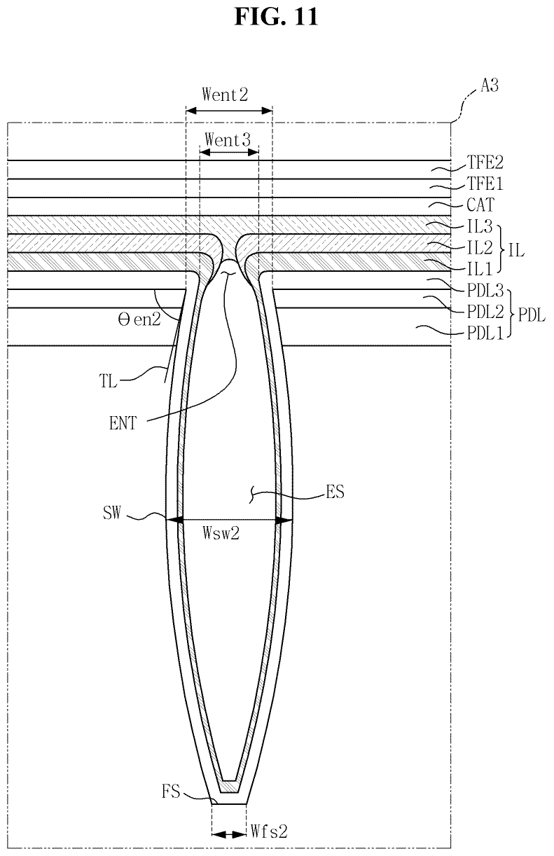

FIG. 10 is a schematic cross-sectional view showing another example of an area A1 of FIG. 7. FIG. 11 is a schematic cross-sectional view illustrating an example of an area A3 of FIG. 10.

FIGS. 10 and 11 may be different from the embodiment of FIGS. 8 and 9 in that the trench TRC may not penetrate the third pixel defining layer PDL3. In FIGS. 10 and 11, the description will be directed to differences from the embodiment of FIGS. 8 and 9.

Referring to FIGS. 10 and 11, the trench TRC may be defined as a hole that penetrates the first pixel defining layer PDL1 and the second pixel defining layer PDL2, and in which the tenth insulating layer INS10 is partially recessed. The third pixel defining layer PDL3 may be disposed on the sidewall SW and lower surface FS of the trench TRC. The trench TRC may be formed by a lithography process using krypton fluoride (KrF) as a photoresist.

The trench TRC may include the entrance ENT, the sidewall SW, and the lower surface FS.

The entrance ENT of the trench TRC may be an open area at the top of the trench TRC defined by the second pixel defining layer PDL2. The entrance ENT of the trench TRC may be covered by the light emitting stack IL. For example, the third pixel defining layer PDL3, the first stack layer IL1, and the second stack layer IL2 may be sequentially disposed at the edge of the entrance ENT of the trench TRC. The entrance ENT of the trench TRC exposed without being covered by the third pixel defining layer PDL3, the first stack layer IL1, and the second stack layer IL2 may be covered by the third stack layer IL3.

The sidewall SW of the trench TRC may be a side surface that connects the entrance ENT of the trench TRC to the lower surface FS thereof. The sidewall SW of the trench TRC may be defined by the tenth insulating layer INS10, the first pixel defining layer PDL1, and the second pixel defining layer PDL2. The length of the sidewall SW of the trench TRC defined by the tenth insulating layer INS10 may be larger than the length of the sidewall SW of the trench TRC defined by the first pixel defining layer PDL1 and the second pixel defining layer PDL2. The sum of the thickness of the first pixel defining layer PDL1 and the thickness of the second pixel defining layer PDL2 may be smaller than or equal to ¼ of the height Htrc of the trench TRC.

In order to cut off the first to second stack layers IL1 and IL2, the first charge generation layer, and the second charge generation layer in the trench TRC, an angle θent2 formed between a tangent TL of the sidewall SW of the trench TRC and the upper surface of the second pixel defining layer PDL2 at the entrance of the trench TRC may range from about 80° to about 90°. Accordingly, a maximum width Wsw2 of the trench TRC in one direction or a direction at the center of the sidewall SW may be larger than a width Went2 of the entrance ENT in one direction or a direction and a width Wfs2 of the lower surface FS in one direction or a direction. The width Wfs2 of the lower surface of the trench TRC in one direction or a direction may be less than the width Went2 of the entrance ENT of the trench TRC in one direction or a direction. For example, the trench TRC may have a substantially jar-shaped cross section.

On the other hand, in case that the trench TRC is formed by a photolithography process using krypton fluoride (KrF), it is difficult to control the width Went2 of the entrance ENT of the trench TRC to be less than about 130 nm. In case that the width Went2 of the entrance of the trench TRC is greater than about 130 nm, it may occur that the first to second stack layers IL1 and IL2, the first charge generation layer, and the second charge generation layer are not cut off in the trench TRC. Therefore, the third pixel defining layer PDL3 may be disposed to surround the sidewall SW and the lower surface FS of the trench TRC. For example, a width Went3 of the entrance ENT of the trench TRC redefined by the third pixel defining layer PDL3 may be greater than about 100 nm and less than about 130 nm. Therefore, the first to second stack layers IL1 and IL2, the first charge generation layer, and the second charge generation layer may be reliably cut off in the trench TRC.

The third pixel defining layer PDL3, the first stack layer IL1, and the second stack layer IL2 may be sequentially disposed at the edge of the entrance ENT of each trench TRC. The third pixel defining layer PDL3 may be disposed closer to the edge of the entrance ENT of each trench TRC than the first stack layer IL1. Further, the first stack layer IL1 may be disposed closer to the edge of the entrance ENT of each trench TRC than the second stack layer IL2. The third stack layer IL3 may be disposed to cover the remaining portion of the entrance ENT of each trench TRC that is not covered by the third pixel defining layer PDL3, the first stack layer IL1, and the second stack layer IL2.

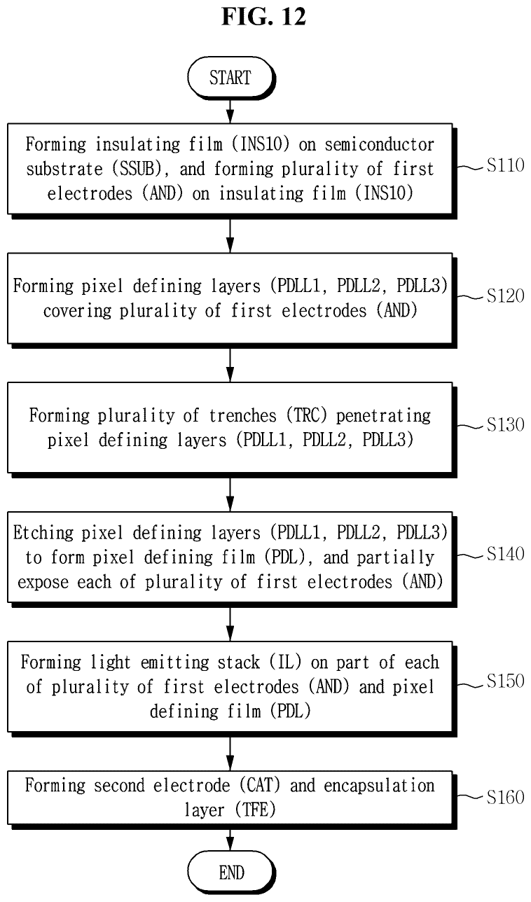

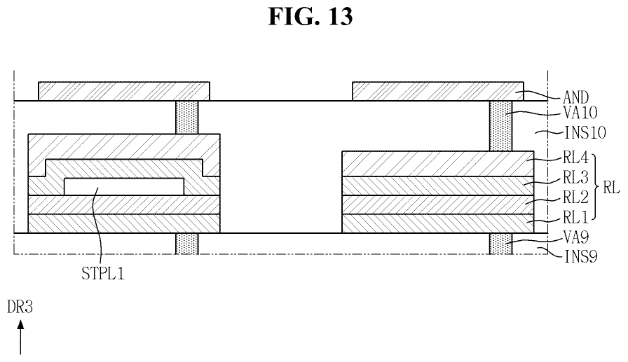

FIG. 12 is a flowchart illustrating a method for manufacturing a display panel according to an embodiment. FIGS. 13 to 18 are schematic cross-sectional views showing an area A1 in detail to describe a method for manufacturing a display panel according to an embodiment.

Hereinafter, the method for manufacturing the display panel according to an embodiment will be described in detail with reference to FIG. 7 and FIGS. 12 to 18.

First, as shown in FIG. 13, the semiconductor backplane SBP is formed on the semiconductor substrate SSUB, and a plurality of first electrodes AND are formed on the semiconductor backplane SBP (step S110 of FIG. 12).

The light emitting element backplane EBP is formed on the semiconductor backplane SBP, and a first electrode layer and a passivation layer may be formed on the light emitting element backplane EBP.

The first to eighth conductive layers ML1 to ML8, the first to ninth vias VA1 to VA9, and the first to ninth insulating layers INS1 to INS9 of the light emitting element backplane EBP are formed on the semiconductor substrate SSUB.

By way of example, the first insulating layer INS1 is formed on the semiconductor substrate SSUB, the first vias VA1 respectively connected to the contact terminals CTE of the semiconductor substrate SSUB while penetrating the first insulating layer INS1 are formed by a photolithography process, and the first conductive layers ML1 respectively connected to the first vias VA1 are formed on the first insulating layer INS1 by a photolithography process. The second insulating layer INS2 may be formed on the first conductive layers ML1, the second vias VA2 respectively connected to the first conductive layers ML1 while penetrating the second insulating layer INS2 are formed by a photolithography process, and the second conductive layers ML2 respectively connected to the second vias VA2 are formed on the second insulating layer INS2 by a photolithography process. The third insulating layer INS3 may be formed on the second conductive layers ML2, the third vias VA3 respectively connected to the second conductive layers ML2 while penetrating the third insulating layer INS3 are formed by a photolithography process, and the third conductive layers ML3 respectively connected to the third vias VA3 are formed on the third insulating layer INS3 by a photolithography process. The fourth insulating layer INS4 may be formed on the third conductive layers ML3, the fourth vias VA4 respectively connected to the third conductive layers ML3 while penetrating the fourth insulating layer INS4 are formed by a photolithography process, and the fourth conductive layers ML4 respectively connected to the fourth vias VA4 are formed on the fourth insulating layer INS4 by a photolithography process.

The fifth insulating layer INS5 may be formed on the fourth conductive layers ML4, the fifth vias VA5 respectively connected to the fourth conductive layers ML4 while penetrating the fifth insulating layer INS5 are formed by a photolithography process, and the fifth conductive layers ML5 respectively connected to the fifth vias VA5 are formed on the fifth insulating layer INS5 by a photolithography process. The sixth insulating layer INS6 may be formed on the fifth conductive layers ML5, the sixth vias VA6 respectively connected to the fifth conductive layers ML5 while penetrating the sixth insulating layer INS6 are formed by a photolithography process, and the sixth conductive layers ML6 respectively connected to the sixth vias VA6 are formed on the sixth insulating layer INS6 by a photolithography process. The seventh insulating layer INS7 may be formed on the sixth conductive layers ML6, the seventh vias VA7 respectively connected to the sixth conductive layers ML6 while penetrating the seventh insulating layer INS7 are formed by a photolithography process, and the seventh conductive layers ML7 respectively connected to the seventh vias VA7 are formed on the seventh insulating layer INS7 by a photolithography process. The eighth insulating layer INS8 may be formed on the seventh conductive layers ML7, the eighth vias VA8 respectively connected to the seventh conductive layers ML7 while penetrating the eighth insulating layer INS8 are formed by a photolithography process, and the eighth conductive layers ML8 respectively connected to the eighth vias VA8 are formed on the eighth insulating layer INS8 by a photolithography process. The ninth insulating layer INS9 may be formed on the eighth conductive layers ML8, and the ninth vias VA9 respectively connected to the eighth conductive layers ML8 while penetrating the ninth insulating layer INS9 are formed on the ninth insulating layer INS9 by a photolithography process.

The first reflective electrodes RL1 of the reflective electrode layer RL that are respectively connected to the ninth vias VA9 may be formed on the ninth insulating layer INS9, and the second reflective electrodes RL2 of the reflective electrode layer RL are respectively formed on the first reflective electrodes RL1. A first step layer STPL1 may be formed on the second reflective electrodes RL2 of the reflective electrode layer RL in the second sub-pixel SP2 and the third sub-pixel SP3, and a second step layer STPL2 is formed on the first step layer STPL1 in the third sub-pixel SP3. Thereafter, the third reflective electrodes RL3 of the reflective electrode layer RL are respectively formed on the second reflective electrode RL2 of the reflective electrode layer RL in the first sub-pixel SP1, the first step layer STPL1 in the second sub-pixel SP2, and the second step layer STPL2 in the third sub-pixel SP3, and the fourth reflective electrodes RL4 of the reflective electrode layer RL respectively formed on the third reflective electrodes RL3 of the reflective electrode layer RL.

The tenth insulating layer INS10 covering the reflective electrode layer RL may be formed, and the tenth vias VA10, which penetrate the tenth insulating layer INS10 to be respectively connected to the fourth reflective electrodes RL4, may be formed. Further, the plurality of first electrodes AND connected correspondingly to the tenth vias VA10 may be formed on the tenth insulating layer INS10.

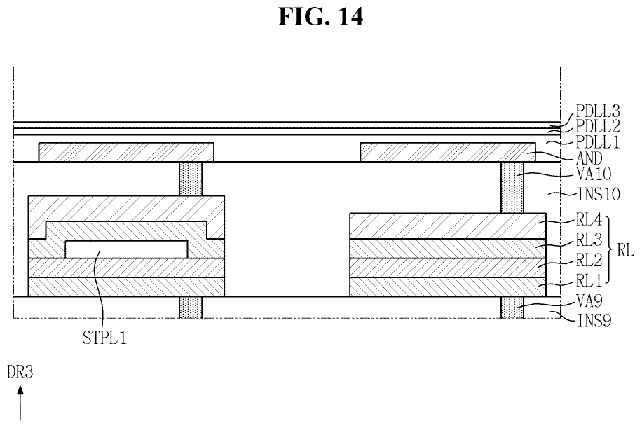

Second, as shown in FIG. 14, pixel defining layers PDLL1, PDLL2, and PDLL3 covering the plurality of first electrodes AND are formed (step S120 of FIG. 12).

The pixel defining layers PDLL1, PDLL2, and PDLL3 include a first pixel defining layer PDLL1, a second pixel defining layer PDLL2, and a third pixel defining layer PDLL3. The first pixel defining layer PDLL1 may be formed to cover the plurality of first electrodes AND. The first pixel defining layer PDLL1 may be formed to cover the upper surface and side surface of each of the first electrodes AND. The second pixel defining layer PDLL2 may be formed on the first pixel defining layer PDLL1, and the third pixel defining layer PDLL3 may be formed on the second pixel defining layer PDLL2. The first pixel defining layer PDLL1, the second pixel defining layer PDLL2, and the third pixel defining layer PDLL3 may be made of silicon oxide (SiOₓ).

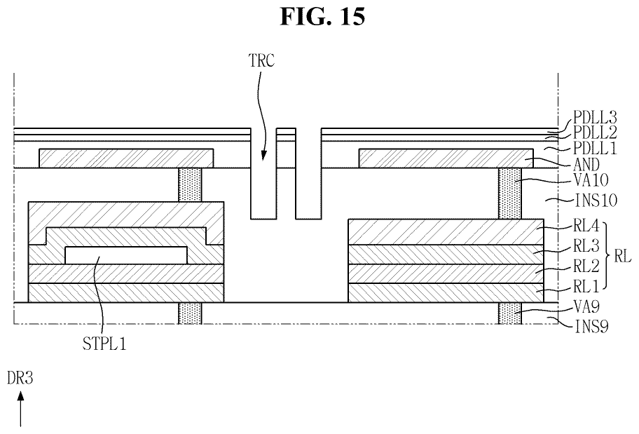

Third, as shown in FIG. 15, the plurality of trenches TRC are formed to penetrate the pixel defining layers PDLL1, PDLL2, and PDLL3 (step S130 of FIG. 12).

Each of the trenches TRC may be a hole that penetrates the first pixel defining layer PDLL1, the second pixel defining layer PDLL2, and the third pixel defining layer PDLL3, and in which the tenth insulating layer INS10 is partially recessed. The plurality of trenches TRC may be formed by a lithography process using argon fluoride (ArF) as a photoresist. For example, as shown in FIG. 9, the width Went1 of the entrance ENT of the trench TRC may be formed to be greater than about 100 nm and less than about 130 nm, so that the first to second stack layers IL1 and IL2, the first charge generation layer, and the second charge generation layer may be reliably cut off in the trench TRC.

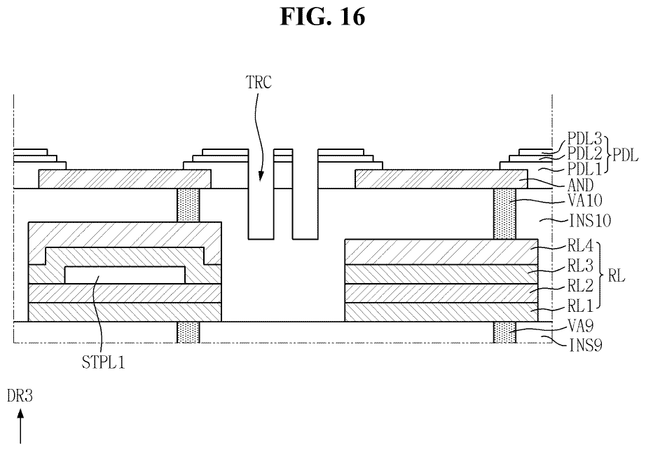

Fourth, as shown in FIG. 16, the pixel defining layers PDLL1, PDLL2, and PDLL3 are etched to form the pixel defining layer PDL and partially expose each of the first electrodes AND (step S140 of FIG. 12).

First, a first mask pattern is formed on the third pixel defining layer PDLL3, and the third pixel defining layer PDLL3 that is not covered by the first mask pattern is etched to form the third pixel defining layer PDL3.

A second mask pattern covering a portion of the second pixel defining layer PDLL2 and the third pixel defining layer PDL3 may be formed, and the second pixel defining layer PDLL2 that is not covered by the second mask pattern is etched to form the second pixel defining layer PDL2.

A third mask pattern covering a portion of the first pixel defining layer PDLL1, the second pixel defining layer PDL2, and the third pixel defining layer PDL3 may be formed, and the first pixel defining layer PDLL1 that is not covered by the third mask pattern is etched to form the first pixel defining layer PDL1. Accordingly, since the pixel defining layer PDL covers only the edge of each of the first electrodes AND, a central portion of each of the first electrodes AND may be exposed.

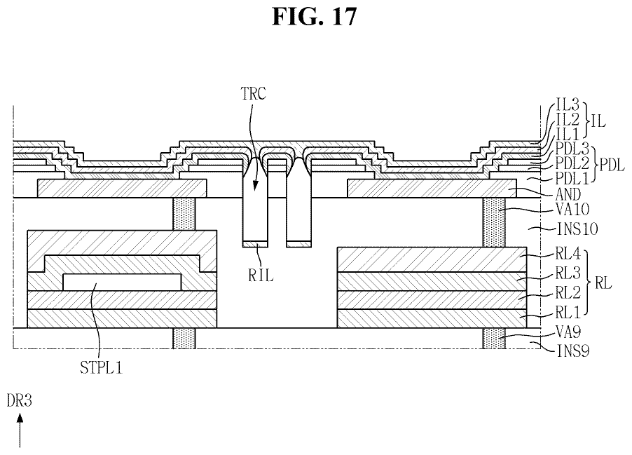

Fifth, as shown in FIG. 17, the light emitting stack IL is formed on a portion of each of the first electrodes AND and the pixel defining layer PDL (step S150 of FIG. 12).

The first stack layer IL1, the second stack layer IL2, and the third stack layer IL3 of the light emitting stack IL may be formed on the plurality of first electrodes AND, the first pixel defining layer PDL1, the second pixel defining layer PDL2 and the third pixel defining layer PDL3. The first stack layer IL1 and the second stack layer IL2 may be cut off in each of the trenches TRC. Therefore, the first charge generation layer disposed between the first stack layer IL1 and the second stack layer IL2 and the second charge generation layer disposed between the second stack layer IL2 and the third stack layer IL3 may also be cut off. Accordingly, the current flowing in each of the sub-pixels SP1, SP2, and SP3 may be prevented from flowing to the neighboring sub-pixel through the first charge generation layer and the second charge generation layer.

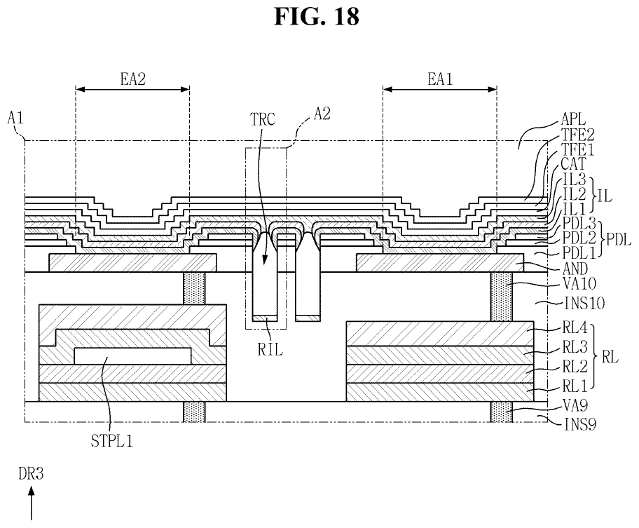

Sixth, as shown in FIG. 18, the second electrode CAT and the encapsulation layer TFE are sequentially formed on the light emitting stack IL (step S160 of FIG. 12).

The second electrode CAT is formed on the third stack layer IL3, and the first encapsulation inorganic layer TFE1 and the second encapsulation inorganic layer TFE2 of the encapsulation layer TFE are sequentially formed on the second electrode CAT. The first encapsulation inorganic layer TFE1 may be formed by a chemical vapor deposition (CVD) process, and the second encapsulation inorganic layer TFE2 may be formed by an atomic layer deposition (ALD) process.

The organic layer APL is formed on the encapsulation layer TFE, and the first color filters CF1 overlapping the first emission areas EA1, the second color filters CF2 overlapping the second emission areas EA2, and the third color filters CF2 overlapping the third emission areas EA3 may be formed on the organic layer APL.

Thereafter, the plurality of lenses LNS are formed on the first color filters CF1, the second color filters CF2, and the third color filters CF3, respectively. For example, the plurality of lenses LNS may be formed to correspond one-to-one to the color filters CF1, CF2, and CF3.

The filling layer FIL is formed on the plurality of lenses LNS, and the cover layer CVL may be provided on the filling layer FIL.

The cover layer CVL may be a glass substrate or a polymer resin. In case that the cover layer CVL is a glass substrate, it may serve as an encapsulation substrate, and the filling layer FIL may serve to adhere the cover layer CVL. In case that the cover layer CVL is a polymer resin, it may be directly applied onto the filling layer FIL.

The polarizing plate POL may be attached on the cover layer CVL.

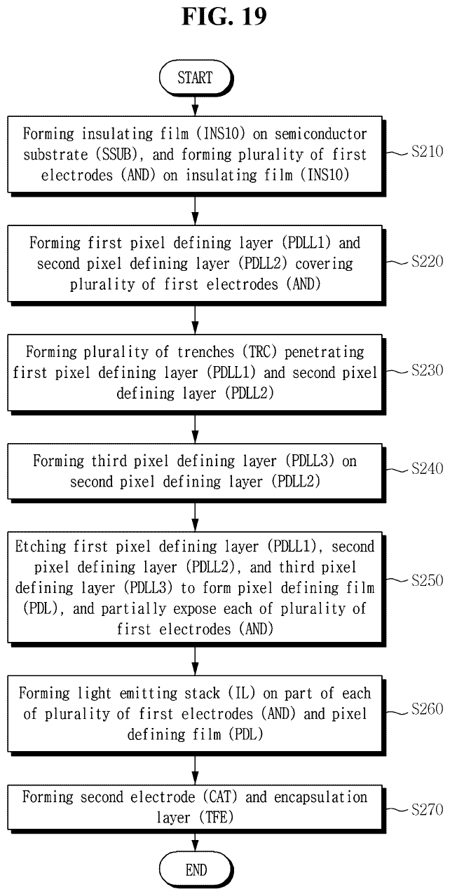

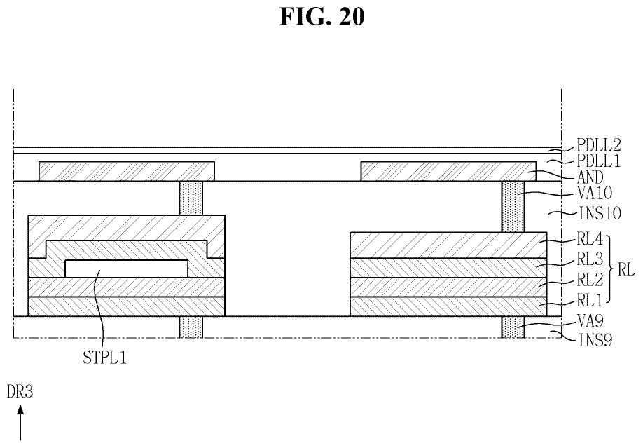

FIG. 19 is a flowchart illustrating a method for manufacturing a display panel according to an embodiment. FIGS. 20 to 24 are schematic cross-sectional views showing an area A1 in detail to describe a method for manufacturing a display panel according to an embodiment.

Hereinafter, a method for manufacturing a display panel according to an embodiment will be described in detail with reference to FIG. 7 and FIGS. 19 to 24.

First, as shown in FIG. 20, the semiconductor backplane SBP is formed on the semiconductor substrate SSUB, and the plurality of first electrodes AND are formed on the semiconductor backplane SBP (step S210 of FIG. 19).

Since step S210 of FIG. 19 is substantially the same as step S110 of FIG. 12, detailed description of step S210 of FIG. 19 may be omitted.

Second, as shown in FIG. 20, the first pixel defining layer PDLL1 and the second pixel defining layer PDLL2 covering the plurality of first electrodes AND are formed (step S220 of FIG. 19).

The first pixel defining layer PDLL1 may be formed to cover the plurality of first electrodes AND. The first pixel defining layer PDLL1 may be formed to cover the upper surface and side surface of each of the first electrodes AND. The second pixel defining layer PDLL2 may be formed on the first pixel defining layer PDLL1. The first pixel defining layer PDLL1 and the second pixel defining layer PDLL2 may be made of silicon oxide (SiOₓ).

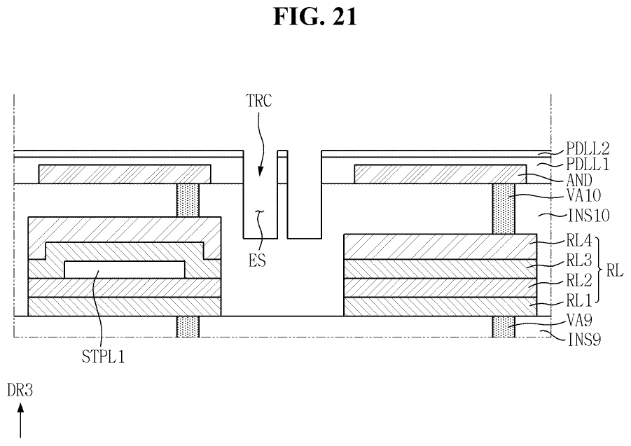

Third, as shown in FIG. 21, the plurality of trenches TRC penetrating the first pixel defining layer PDLL1 and the second pixel defining layer PDLL2 are formed (step S230 of FIG. 19).

Each of the trenches TRC may be a hole that penetrates the first pixel defining layer PDLL1 and the second pixel defining layer PDLL2, and in which the tenth insulating layer INS10 is partially recessed. The plurality of trenches TRC may be formed by a lithography process using krypton fluoride (ArF) as a photoresist.

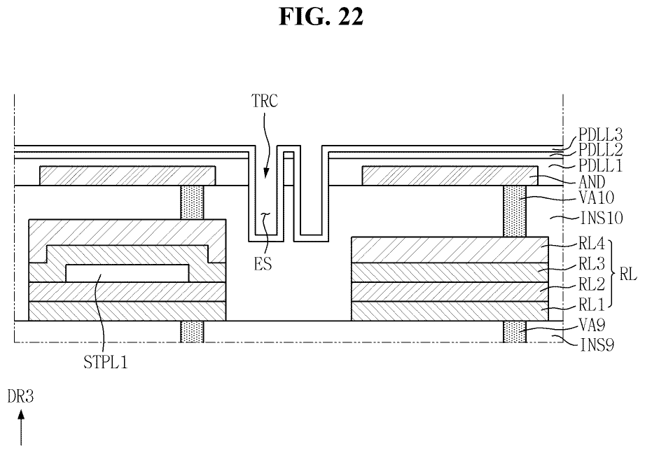

Fourth, as shown in FIG. 22, the third pixel defining layer PDLL3 is formed on the second pixel defining layer PDLL2 (step S240 of FIG. 19).

In case that the trench TRC is formed by a photolithography process using krypton fluoride (KrF), it is difficult to control the width Went2 of the entrance ENT of the trench TRC to be less than about 130 nm as shown in FIG. 11. In case that the width Went2 of the entrance of the trench TRC is greater than about 130 nm, it may occur that the first to second stack layers IL1 and IL2, the first charge generation layer, and the second charge generation layer are not cut off in the trench TRC. Therefore, in case that the third pixel defining layer PDLL3 is formed on the second pixel defining layer PDLL2, the third pixel defining layer PDLL3 may be formed on the sidewall SW and the lower surface FS in each of the trenches TRC. For this reason, as shown in FIG. 11, the width Went3 of the entrance ENT of the trench TRC redefined by the third pixel defining layer PDL3, may be reduced compared to the width Went2 of the entrance ENT of the original trench TRC. For example, the width Went3 of the entrance ENT of the trench TRC redefined by the third pixel defining layer PDL3 may be greater than about 100 nm and less than about 130 nm. Therefore, the first to second stack layers IL1 and IL2, the first charge generation layer, and the second charge generation layer may be reliably cut off in the trench TRC.

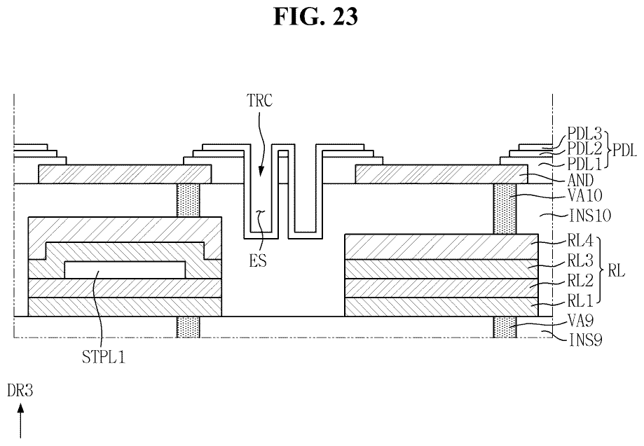

Fifth, as shown in FIG. 23, the first pixel defining layer PDLL1, the second pixel defining layer PDLL2, and the third pixel defining layer PDLL3 are etched to form the pixel defining layer PDL, and partially expose each of the first electrodes AND (step S250 of FIG. 19).

Since step S250 of FIG. 19 is substantially the same as step S140 of FIG. 12, detailed description of step S250 of FIG. 19 may be omitted.

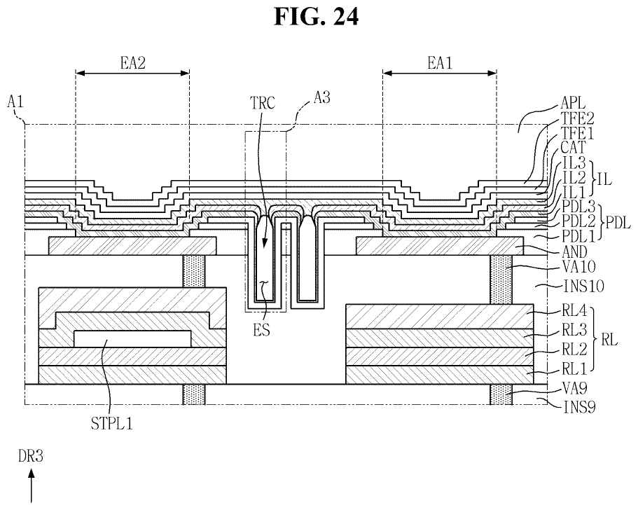

Sixth, as shown in FIG. 24, the light emitting stack IL is formed on a portion of each of the first electrodes AND and the pixel defining layer PDL (step S260 of FIG. 19). Also, the second electrode CAT and the encapsulation layer TFE are formed on the light emitting stack IL (step S270 of FIG. 19).

Since step S260 of FIG. 19 is substantially the same as step S150 of FIG. 12, detailed description of step S260 of FIG. 19 may be omitted.

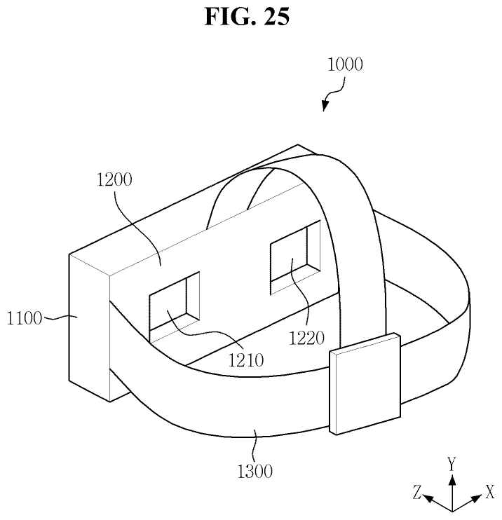

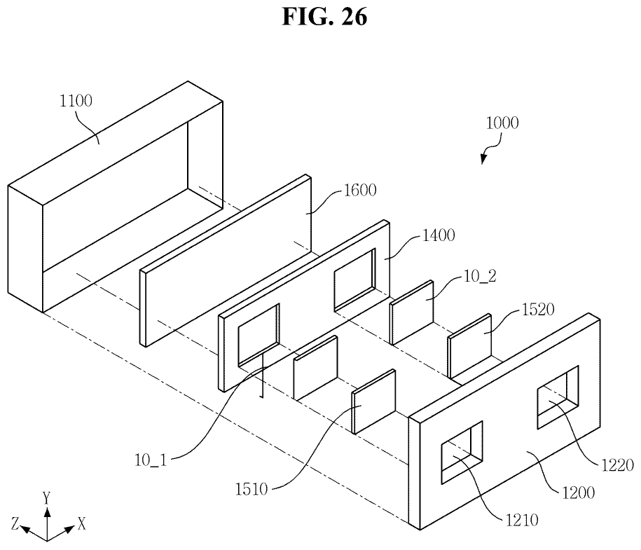

FIG. 25 is a schematic perspective view illustrating a head mounted display according to an embodiment. FIG. 26 is an exploded schematic perspective view illustrating an example of the head mounted display of FIG. 25.

Referring to FIGS. 25 and 26, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 may be substantially the same as the display device 10 described in conjunction with FIGS. 1 and 2, description of the first display device 10_1 and the second display device 10_2 may be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. By way of example, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 25 and 26 illustrate that the first eyepiece 1210 and the second eyepiece 1220 are disposed separately, but the embodiment of the specification is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

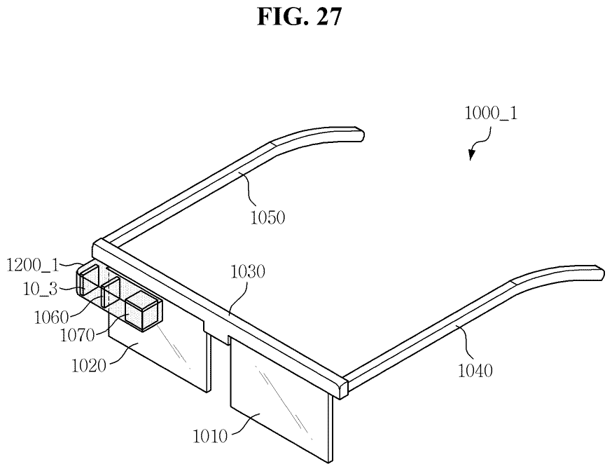

The head mounted band 1300 serves to secure the display device housing 1100 to the user's head such that the first eyepiece 1210 and the second eyepiece 1220 of the housing cover 1200 remain disposed on the user's left and right eyes, respectively. In case that the display device housing 1200 is implemented to be lightweight and compact, the head mounted display 1000 may be provided with, as shown in FIG. 27, an eyeglass frame instead of the head mounted band 1300.

The head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 27 is a schematic perspective view illustrating a head mounted display according to an embodiment.

Referring to FIG. 27, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 27 illustrates that the display device housing 1200_1 is disposed at the right end of the support frame 1030, but the embodiment of the specification is not limited thereto. For example, the display device housing 1200_1 may be disposed at the left end of the support frame 1030, and for example, the image of the display device 10_3 may be provided to the user's left eye. By way of example, the display device housing 1200_1 may be disposed at both the left and right ends of the support frame 1030, and for example, the user may view the image displayed on the display device 10_3 through both the left and right eyes.

It should be understood, however, that the aspects and features of embodiments are not restricted to the ones set forth herein. The above and other aspects of the disclosure will become more apparent to one of ordinary skill in the art to which the disclosure pertains by referencing the claims, with equivalents thereof to be included therein.

What is claimed is:

1. A display device comprising:
an insulating layer disposed on a substrate;
a first electrode disposed on the insulating layer;
a first pixel defining layer covering a portion of the first electrode;
a second pixel defining layer disposed on the first pixel defining layer;
a trench penetrating the insulating layer, the first pixel defining layer, and the second pixel defining layer;
a light emitting stack disposed on an upper surface of the first electrode and the second pixel defining layer; and
a second electrode disposed on the light emitting stack,
wherein a width of an entrance of the trench in a direction is greater than a width of a lower surface of the trench in the direction.

2. The display device of claim 1, wherein a length of a sidewall of the trench defined by the insulating layer is greater than a length of a sidewall of the trench defined by the first pixel defining layer and the second pixel defining layer.

3. The display device of claim 1, wherein a height of the trench is in a range of about 6,000 Å to about 10,000 Å.

4. The display device of claim 1, further comprising:
a third pixel defining layer disposed on the second pixel defining layer,
wherein the trench penetrates the third pixel defining layer.

5. The display device of claim 4, wherein a sum of a thickness of the first pixel defining layer, a thickness of the second pixel defining layer, and a thickness of the third pixel defining layer is less than or equal to about ¼ of a height of the trench.

6. The display device of claim 4, wherein an angle formed between an upper surface of the third pixel defining layer and a tangent of a sidewall of the trench at the entrance of the trench is in a range of about 80° to about 90°.

7. The display device of claim 1, wherein the light emitting stack comprises:
a first stack layer disposed at an edge of the entrance of the trench; and
a second stack layer disposed on the first stack layer.

8. The display device of claim 7, wherein the light emitting stack further comprises a third stack layer disposed on the second stack layer, the third stack layer covering the entrance of the trench.

9. The display device of claim 1, further comprising:
a third pixel defining layer disposed on the second pixel defining layer,
wherein the third pixel defining layer is disposed on a sidewall and the lower surface of the trench.

10. The display device of claim 9, wherein the light emitting stack comprises:
a first stack layer disposed on the third pixel defining layer disposed on the sidewall and the lower surface of the trench; and
a second stack layer disposed on the first stack layer.

11. The display device of claim 10, wherein a thickness of the first stack layer disposed on a sidewall of the trench defined by the insulating layer is less than a thickness of the first stack layer disposed on the lower surface of the trench.

12. The display device of claim 10, wherein a thickness of the first stack layer disposed on a sidewall of the trench defined by the second pixel defining layer is greater than a thickness of the first stack layer disposed on a sidewall of the trench defined by the insulating layer.

13. The display device of claim 10, wherein the light emitting stack further comprises a third stack layer disposed on the second stack layer, the third stack layer covering the entrance of the trench.

14. A method for manufacturing a display device, comprising:
forming an insulating layer on a substrate, and forming a plurality of first electrodes on the insulating layer;
forming a pixel defining layer covering the plurality of first electrodes;
forming a plurality of trenches penetrating the pixel defining layer;
etching the pixel defining layer to form a pixel defining layer, to partially expose each of the plurality of first electrodes;
forming a first stack layer on a portion of each of the plurality of first electrodes and the pixel defining layer;
forming a second stack layer on the first stack layer; and
forming a second electrode covering the second stack layer,
wherein the first stack layer is disposed at an edge of an entrance of the trench, and the second stack layer covers the entrance of the trench.

15. The method of claim 14, wherein the forming of the pixel defining layer comprises forming a first pixel defining layer covering the first electrodes, forming a second pixel defining layer covering the first pixel defining layer, and forming a third pixel defining layer covering the second pixel defining layer.

16. The method of claim 15, wherein the etching of the pixel defining layer to form the pixel defining layer, to partially expose each of the plurality of first electrodes comprises:
forming a first mask pattern on a portion of the third pixel defining layer, and etching the third pixel defining layer which is not covered by the first mask pattern to form a third pixel defining layer;
forming a second mask pattern on a portion of the second pixel defining layer and all parts of the third pixel defining layer, and etching the second pixel defining layer which is not covered by the second mask pattern to form a second pixel defining layer; and
forming a third mask pattern on a portion of the first pixel defining layer, and all parts of the second pixel defining layer and the third pixel defining layer, and etching the first pixel defining layer which is not covered by the third mask pattern to partially expose each of the first electrodes.

17. A method for manufacturing a display device, the method comprising:
forming an insulating layer on a substrate, and forming a plurality of first electrodes on the insulating layer;
forming a first pixel defining layer covering the plurality of first electrodes, and forming a second pixel defining layer on the first pixel defining layer;
forming a plurality of trenches penetrating the first pixel defining layer and the second pixel defining layer;
forming a third pixel defining layer on the second pixel defining layer;
etching each of the first pixel defining layer, the second pixel defining layer, and the third pixel defining layer to form a first pixel defining layer, a second pixel defining layer, and a third pixel defining layer, to partially expose each of the plurality of first electrodes;
forming a first stack layer on a portion of each of the plurality of first electrodes, the first pixel defining layer, the second pixel defining layer, and the third pixel defining layer;
forming a second stack layer on the first stack layer; and
forming a second electrode covering the second stack layer,
wherein the third pixel defining layer is disposed on a sidewall and a lower surface of the trench,
the first stack layer is disposed on the third pixel defining layer disposed on the sidewall and the lower surface of the trench, and
the second stack layer covers an entrance of the trench.

18. The method of claim 17, wherein the forming of the first pixel defining layer and the second pixel defining layer comprises:
forming a first pixel defining layer covering the first electrodes, and
forming a second pixel defining layer covering the first pixel defining layer.

19. The method of claim 18, wherein
the etching of each of the first pixel defining layer, the second pixel defining layer, and the third pixel defining layer to form the first pixel defining layer, the second pixel defining layer, and the third pixel defining layer, to partially expose each of the plurality of first electrodes comprises:
forming a first mask pattern on a portion of the third pixel defining layer, and etching the third pixel defining layer which is not covered by the first mask pattern to form a third pixel defining layer;
forming a second mask pattern on a portion of the second pixel defining layer and all parts of the third pixel defining layer, and etching the second pixel defining layer which is not covered by the second mask pattern to form a second pixel defining layer; and
forming a third mask pattern on a portion of the first pixel defining layer, and all parts of the second pixel defining layer and the third pixel defining layer, and etching the first pixel defining layer which is not covered by the third mask pattern to partially expose each of the first electrodes.

20. A head mounted display comprising:
at least one display device;
a display device housing that accommodates the at least one display device; and
an optical member that magnifies a display image of the at least one display device or that changes an optical path, wherein
the at least one display device comprises:
an insulating layer disposed on a substrate;
a first electrode disposed on the insulating layer;
a first pixel defining layer covering a portion of the first electrode;
a second pixel defining layer disposed on the first pixel defining layer;
a trench penetrating the insulating layer, the first pixel defining layer, and the second pixel defining layer;
a light emitting stack disposed on an upper surface of the first electrode and the second pixel defining layer; and
a second electrode disposed on the light emitting stack,
a width of an entrance of the trench in a direction is greater than a width of a lower surface of the trench in the direction.
